(19) United States
(12) Patent Application Publication
(10) Pub. No.: US 2005/0128770 A1
(43) Pub. Date: Jun. 16, 2005

(54) Electronic apparatus with illumination portion

(76) Inventor: Yi-Kuan Lin, Jhonghe City (TW)

Correspondence Address: RABIN & Berdo, PC, 1101 14TH STREET, NW, SUITE 500, WASHINGTON, DC, 20005, US

(21) Appl. No.: 10/975,359

(22) Filed: Oct. 29, 2004

(30) Foreign Application Priority Data
Dec. 12, 2003 (TW) 92135290

(51) Int. Cl. F21V 7/04; H01L 33/00

(52) U.S. Cl. 362/602

(57) ABSTRACT

An electronic apparatus including a casing, at least a transparent illumination portion, a display and a light guide is provided. The transparent illumination portion is disposed on a surface of the casing while the display is for providing the transparent illumination portion with necessary light. The light guide for projecting the light provided by the display onto the transparent illumination portion has a light receiving end and a light outputting end, wherein the light receiving end is close to the display while the light outputting end is close to the transparent illumination portion.

This application claims the benefit of Taiwan application Serial No. 92135290, filed Dec. 12, 2003, the subject matter of which is incorporated herein by reference.

### BACKGROUND OF THE INVENTION

1. Field of the Invention

The invention relates in general to an electronic apparatus, and more particularly to an electronic apparatus which projects the light provided by the display to the transparent illumination portion of the electronic apparatus via a light guide.

2. Description of the Related Art

Along with the rapid advance in the manufacturing technology of the display panel and the advantages of being light, slim, power saving and low radiation, display panel has been widely applied in electronic apparatus such as personal digital assistant (PDA), notebook, mobile phone, handy computer and webpad. Display panel ranges from liquid crystal display panel (LCD panel) to organic light emitting diode panel (OLED panel). Since the LCD panel is not self-luminous, a backlight module is required to provide necessary light for display purpose. The light source which provides light for a backlight module can be a cold cathode fluorescent lamp (CCFL) or a light emitting diode (LED). To the contrary, the OLED panel is self-luminous and does not require any backlight module.

Normally an electronic apparatus includes a display, an operating interface and a casing. The operating interface which can be a keyboard or buttons for instance is disposed on the top face of the casing while the display is disposed inside the casing. Moreover, if the electronic apparatus further includes a first casing and a pivot, the first casing is pivotally connected to the casing so that the first casing can be opened from or closed to the casing with the top face of the first casing moving towards the top face of the casing. Of which, the display is disposed inside the first casing while the operating interface is disposed on the top face of the casing.

To highlight the keyboard or the buttons, some manufacturers chose to apply a fluorescent coating onto the keyboard or the buttons. Nevertheless, a casing with a fluorescence coated keyboard or buttons will cause environmental problem when it comes to the recycling of the casing.

Moreover, some manufacturers chose to install a light source, an LED for instance, inside the casing to illuminate the keyboard or the buttons, so that the keyboard or the buttons can be more high-lighted. However, the design of installing an LED inside the casing will increase the cost and consume more power as well.

### SUMMARY OF THE INVENTION

It is therefore an object of the invention to provide an electronic apparatus whose design of projecting the light provided by the display onto the keyboard or buttons via a light guide so as to highlight the keyboard or the buttons not only avoids the environmental problem caused by applying a fluorescent coating onto the keyboard or the buttons but also dispenses with the necessity of installing a light source which increases power consumption further.

The invention achieves the above-identified objects by providing an electronic apparatus including a casing, at least a transparent illumination portion, a display and a light guide. The transparent illumination portion is disposed on a surface of the casing while the display is for providing the transparent illumination portion with necessary light. The light guide for projecting the light provided by the display onto the transparent illumination portion has a light receiving end and a light outputting end, wherein the light receiving end is close to the display while the light outputting end is close to the transparent illumination portion.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1A is a sectional view of an electronic apparatus according to preferred embodiment one of the invention;

FIG. 1B is a schematic diagram of the light guide in FIG. 1A comprising a first light guide, a second light guide and a connector;

FIG. 2 is a sectional view of an electronic apparatus according to preferred embodiment two of the invention;

FIG. 3 is a sectional view of an electronic apparatus according to preferred embodiment three of the invention;

FIG. 4 is a sectional view of an electronic apparatus according to preferred embodiment four of the invention;

FIG. 5A is a decomposed sectional view of an electronic apparatus according to preferred embodiment five of the invention;

FIG. 5B is a schematic diagram of the light guide in FIG. 5A comprising a first light guide, a second light guide and a connector;

FIG. 6 is a decomposed sectional view of an electronic apparatus according to preferred embodiment six of the invention;

FIG. 7 is a decomposed sectional view of an electronic apparatus according to preferred embodiment seven of the invention; and

FIG. 8 is a decomposed sectional view of an electronic apparatus according to preferred embodiment eight of the invention.

### DETAILED DESCRIPTION OF THE INVENTION

### Preferred Embodiment One

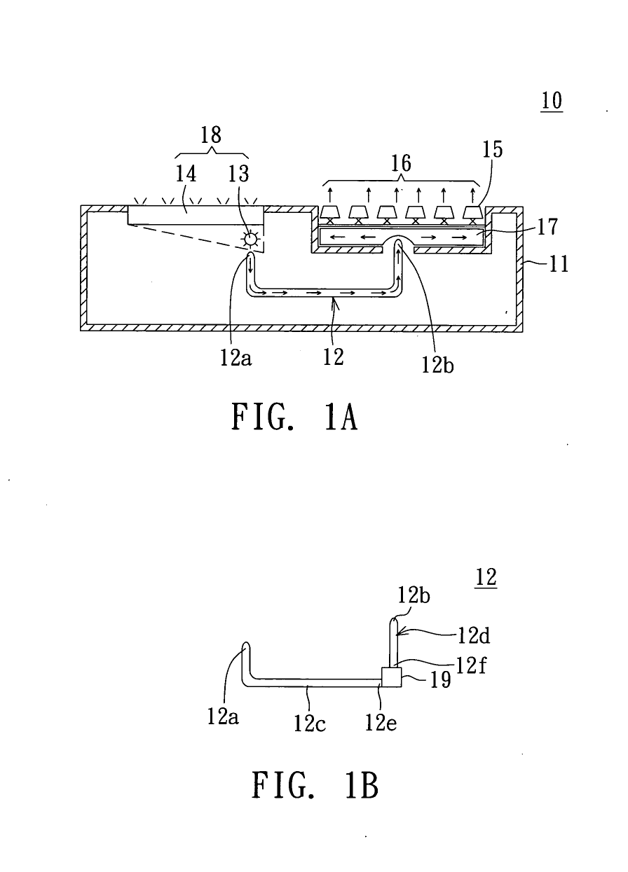

Referring first to FIG. 1A, an electronic apparatus 10 at least includes a casing 11, a light guide 12, a display 18 and a keyboard 15 whose input face has a transparent illumination portion 16. The display 18, which is disposed inside the casing 11, further includes a liquid crystal display panel (LCD panel) 14 and a cold cathode fluorescent lamp (CCFL) 13. Both the LCD panel 14 and the keyboard 15 are disposed on a surface of the casing 11. Of which, the CCFL 13 inside the display 18 can be displaced with a light emitting diode (LED).

The light guide 12 which is disposed inside the casing 11 has a light receiving end 12a and a light outputting end 12b. The light receiving end 12a is close to the display 18, say, in the neighborhood of the CCFL 13 of the display 18, to gather part of the light emitted by the CCFL 13 at the light guide 12. The light outputting end 12b is disposed underneath the keyboard 15, i.e. under the transparent illumination portion 16, for projecting the light directed by the light guide 12 onto the transparent illumination portion 16. The electronic apparatus 10 further includes a diffuser plate 17 which is disposed inside the casing 11 but positioned between the transparent illumination portion 16 and the light outputting end 12b. The diffuser plate 17 is for evenly distributing the light emitted from the light outputting end 12b onto the transparent illumination portion 16 so that the press keys on the keyboard 15 can be highlighted.

Referring to FIG. 1B, the light guide 12 further includes a first light guide 12c, a second light guide 12d and a connector 19. One end of the first light guide 12c is the light receiving end 12a while the other end of the first light guide 12c is a first connecting end 12e. One end of the second light guide 12d is the light outputting end 12b while the other end of the second light guide 12d is a second connecting end 12f. The connector 19 which is disposed inside the casing 11 is for connecting the first connecting end 12e and the second connecting end 12f.

### Preferred Embodiment Two

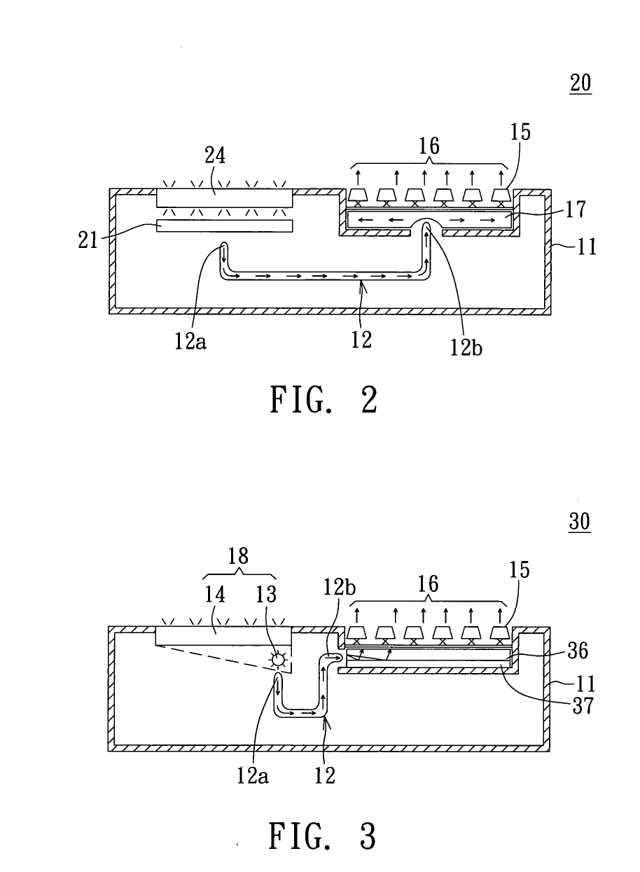

Referring to FIG. 2, a sectional view of an electronic apparatus according to preferred embodiment two of the invention. The electronic apparatus 20 in the present preferred embodiment differs from the electronic apparatus 10 in preferred embodiment one in that the light directed by the light guide 12 in preferred embodiment two originates from an organic light emitting diode panel (OLED panel) 24. The two preferred embodiments are identical to each other except the above-disclosed difference, so the similarities including the numbering system are not repeated here. In FIG. 2, the OLED panel 24 is disposed inside the casing 11 with the light receiving end 12a being close to the OLED panel 24 so that the OLED panel 24 can provide the transparent illumination portion 16 with necessary light. To improve the intensity of the light received by the light receiving end 12a, the present preferred embodiment can further install a light gathering device 21 inside the casing 11. The light gathering device 21 is disposed between the OLED panel 24 and the light receiving end 12a for gathering the light provided by the OLED panel 24 onto the light guide 12.

### Preferred Embodiment Three

Referring to FIG. 3, a sectional view of an electronic apparatus according to preferred embodiment three of the invention. The electronic apparatus 30 in the present preferred embodiment differs from the electronic apparatus 10 in preferred embodiment one in that the former has a diffuser plate 36 and a reflecting plate 37. The two preferred embodiments are identical to each other except the above-disclosed difference, so the similarities including the numbering system are not repeated here. In FIG. 3, both the diffuser plate 36 and the reflecting plate 37 are disposed inside the casing 11 but positioned underneath the keyboard 15, i.e. underneath the transparent illumination portion 16. The light outputting end 12b is disposed at a lateral side of the diffuser plate 36. The diffuser plate 36 is for evenly distributing the light emitted from the light outputting end 12b. The reflecting plate 37 which is disposed underneath the bottom side of the diffuser plate 36 is for reflecting the light directed by the diffuser plate 36 to the transparent illumination portion 16.

### Preferred Embodiment Four

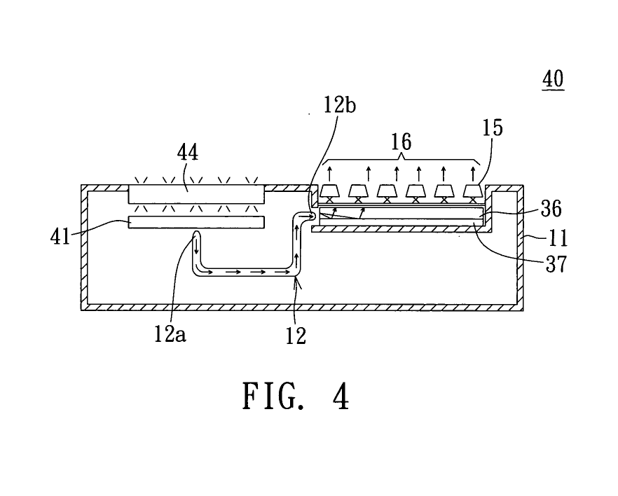

Referring to FIG. 4, a sectional view of an electronic apparatus according to preferred embodiment four of the invention. The electronic apparatus 40 in the present preferred embodiment differs from the electronic apparatus 30 in preferred embodiment three in that the light directed by the light guide 12 originates from an organic light emitting diode panel (OLED panel) 44. The two preferred embodiments are identical to each other except the above-disclosed difference, so the similarities including the numbering system are not repeated here. In FIG. 4, the OLED panel 44 is disposed inside the casing 11 with the light receiving end 12a being close to the OLED panel 44 so that the OLED panel 44 can provide the transparent illumination portion 16 with necessary light. To improve the intensity of the light received by the light receiving end 12a, the present preferred embodiment can further install a light gathering device 41 inside the casing 11. The light gathering device 41 is disposed between the OLED panel 44 and the light receiving end 12a for gathering the light provided by the OLED panel 44 onto the light guide 12.

### Preferred Embodiment Five

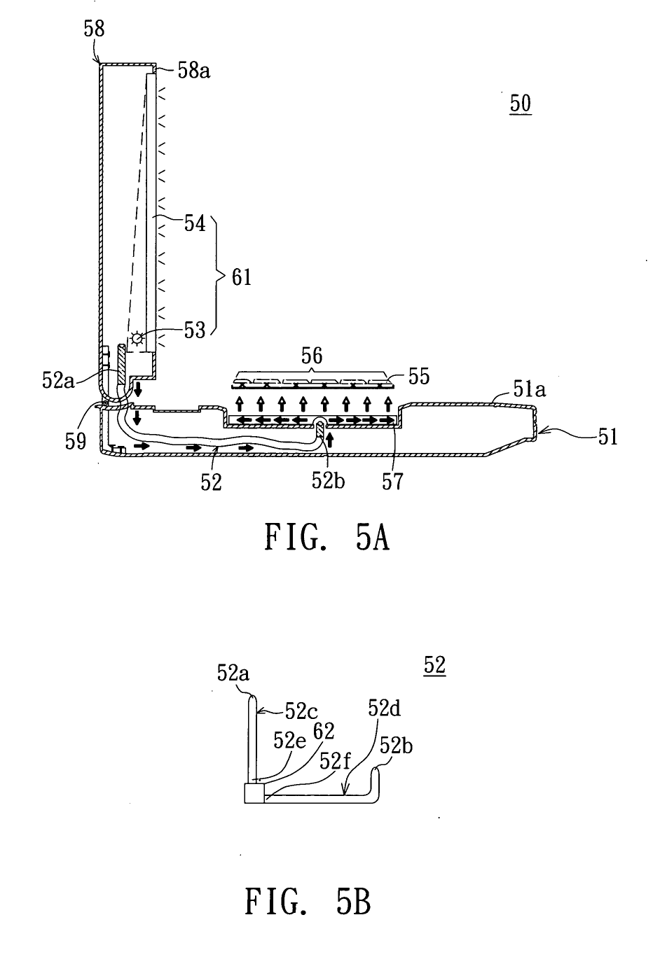

Referring to FIG. 5A, a decomposed sectional view of an electronic apparatus according to preferred embodiment five of the invention. The electronic apparatus 50 includes at least a second casing 51, a first casing 58, a pivot 59, a light guide 52, a display 61 and a keyboard 55 whose input face has a transparent illumination portion 56. The second casing 51 has a casing's surface 58a while the first casing 58 has a first casing's surface 58a. One side of the first casing 58 is pivotally connected to one side of the second casing 51, so that the first casing 58 can be closed to or opened from the second casing 51 with the first casing's surface 58a moving towards the casing's surface 51a. The display 61 which is displaced inside the first casing 58 further includes a CCFL 53 and an LCD panel 54. The LCD panel 54 is displaced on the casing's surface 58a while the CCFL 53 is displaced inside the first casing 58 for providing the LCD panel 54 and the transparent illumination portion 56 with necessary light.

The keyboard 55 is disposed on the casing's surface 51a. The light guide 52, which has a light receiving end 52a and a light outputting end 52b, is disposed inside the second casing 51 and the first casing 58 via the pivot 59. The light receiving end 52a disposed close to the CCFL 53 is for gathering part of the light emitted by CCFL 53 onto the light guide 52. The light outputting end 52b, which is disposed inside the second casing 51 but positioned underneath the keyboard 55, i.e., underneath the transparent illumination portion 56, is for projecting the light directed by the light guide 52 to the transparent illumination portion 56. Moreover, the electronic apparatus 50 further includes a diffuser plate 57, which is disposed inside the second casing 51 but positioned between the transparent illumination portion 56 and the light outputting end 52b, for evenly distributing the light emitted by the light outputting end 52b onto the transparent illumination portion 56 so that the keys on the keyboard 55 can be better high-lighted. It is noteworthy that a reflecting material can be further applied onto a lateral side of the diffuser plate 57 according to the invention so that the light received by the diffuser plate 57 can be completely projected onto the transparent illumination portion 56 via the front side of the diffuser plate 57.

As shown in FIG. 5B, the light guide 52 further includes a first light guide 52c, a second light guide 52d and a connector 62. Of which, one end of the first light guide 52c is the light receiving end 52a while the other end of the first light guide 52c is a first connector 52e; one end of the second light guide 52d is the light outputting end 52b while the other end of the second light guide 52d is a second connector 52f. The connector 62 is disposed inside the second casing 51 in FIG. 5A for photoconductively connecting the first connector 52e and the second connector 52f.

### Preferred Embodiment Six

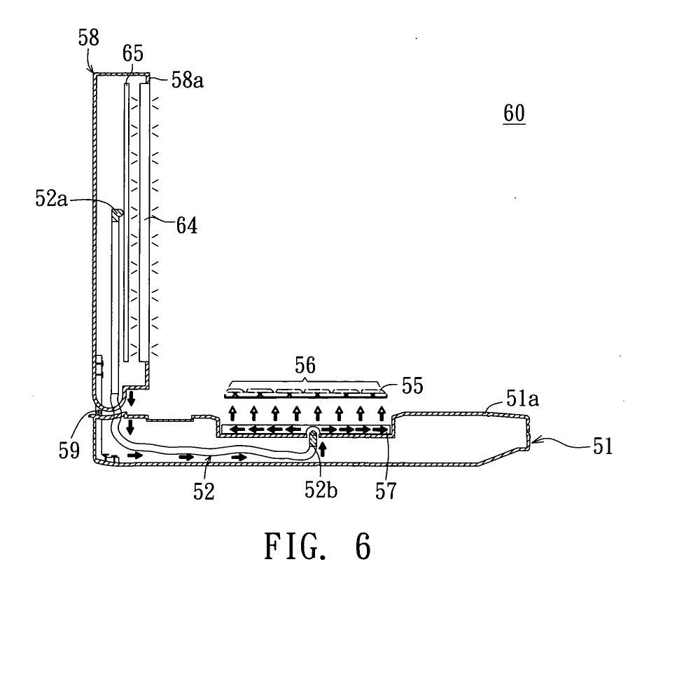

Referring to FIG. 6, a decomposed sectional view of an electronic apparatus according to preferred embodiment six of the invention. The electronic apparatus 60 in the present preferred embodiment differs from the electronic apparatus 50 in preferred embodiment five in that the light directed by the light guide 52 originates from an OLED panel 64. The two preferred embodiments are identical to each other except the above-disclosed difference, so the similarities including the numbering system are not repeated here. In FIG. 6, the OLED panel 64 is disposed inside the first casing 58 with the light receiving end 52a being close to the OLED panel 64 so that the OLED panel 64 can provide the transparent illumination portion 56 with necessary light. To improve the intensity of the light received by the light receiving end 52a, the present preferred embodiment can further install a light gathering device 65 inside the first casing 58. The light gathering device 65 is disposed between the OLED panel 64 and the light receiving end 52a for gathering the light provided by the OLED panel 64 onto the light guide 52.

### Preferred Embodiment Seven

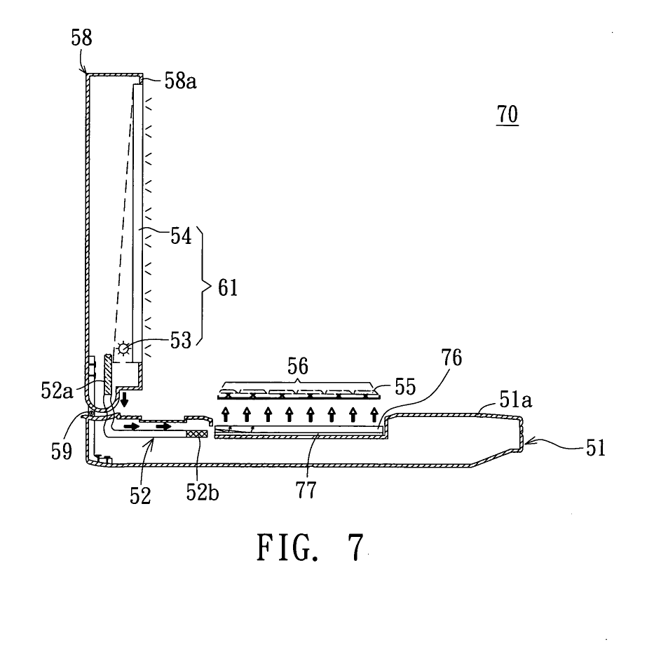

Referring to FIG. 3, a decomposed sectional view of an electronic apparatus according to preferred embodiment seven of the invention. The electronic apparatus 70 in the present preferred embodiment differs from the electronic apparatus 50 in preferred embodiment five in a diffuser plate 76 and a reflecting plate 77. The two preferred embodiments are identical to each other except the above-disclosed difference, so the similarities including the numbering system are not repeated here. In FIG. 7, both the diffuser plate 76 and the reflecting plate 77 are disposed inside the second casing 51 but positioned underneath the keyboard 55, i.e. underneath the transparent illumination portion 16. The light outputting end 52b is disposed at a lateral side of the diffuser plate 76. The diffuser plate 76 is for evenly distributing the light emitted from the light outputting end 52b. The reflecting plate 77 disposed on the bottom side of the diffuser plate 76 is for reflecting the light directed by the diffuser plate 76 to the transparent illumination portion 56. It is noteworthy that a reflecting material can be further applied onto other lateral sides of the diffuser plate 76 so that the light received by the diffuser plate 76 can be completely projected onto the transparent illumination portion 56 via the front side of the diffuser plate 76.

### Preferred Embodiment Eight

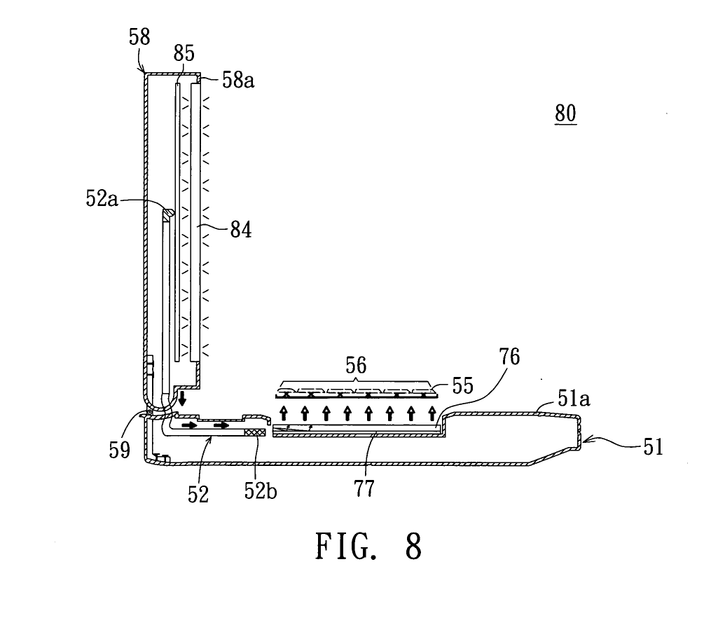

Referring to FIG. 8, a decomposed sectional view of an electronic apparatus according to preferred embodiment eight of the invention. The electronic apparatus 80 in the present preferred embodiment differs from the electronic apparatus 70 in preferred embodiment seven in that the light directed by the light guide 52 originates from an OLED panel 84. The two preferred embodiments are identical to each other except the above-disclosed difference, so the similarities including the numbering system are not repeated here. In FIG. 8, the OLED panel 84 is disposed inside the first casing 58 with the light receiving end 52a being close to the OLED panel 84 so that the OLED panel 84 can provide the transparent illumination portion 56 with necessary light. To improve the intensity of the light received by the light receiving end 52a, the present preferred embodiment can further install a light gathering device 85 inside the first casing 58. The light gathering device 85 is disposed between the OLED panel 84 and the light receiving end 52a for gathering the light provided by the OLED panel 84 onto the light guide 52.

Anyone who is familiar with the above technology will understand that the technology of the invention is not limited thereto. For example, the light guide disclosed in the above preferred embodiments is an optical fiber, wherein the optical fiber can be a plastic fiber, a polymethyl methacrylate fiber (PMMA fiber) or a glass fiber. Besides, the transparent illumination portion disclosed in the above preferred embodiments can be the top face of a press key or the identification symbol region. Furthermore, the light of the transparent illumination portion can be provided by the display of the electronic apparatus or other built-in luminous bodies.

While the invention has been described by way of example and in terms of a preferred embodiment, it is to be understood that the invention is not limited thereto. On the contrary, it is intended to first casing various modifications and similar arrangements and procedures, and the scope of the appended claims therefore should be accorded the broadest interpretation so as to encompass all such modifications and similar arrangements and procedures.

1. An electronic apparatus with illumination portion, comprising:
a transparent illumination portion;
a display; and
a light guide which has a light receiving end for receiving part of the light emitted by the display and a light outputting end for transmitting the light to the transparent illumination portion.

2. The electronic apparatus with illumination portion according to claim 1, wherein the display further comprises a cold cathode fluorescent lamp (CCFL).

3. The electronic apparatus with illumination portion according to claim 1, wherein the display further comprises a light emitting diode (LED).

4. The electronic apparatus with illumination portion according to claim 1, wherein the display further comprises an organic light emitting diode (OLED) display panel.

5. The electronic apparatus with illumination portion according to claim 4, further comprises a light gathering device disposed between the OLED display panel and the light receiving end.

6. The electronic apparatus with illumination portion according to claim 1, further comprising a first casing, a second casing, and at least a pivot, wherein the first casing is pivotally connected to the second casing, the display is disposed inside the first casing, the light guide is disposed inside the first casing and the second casing via the pivot.

7. The electronic apparatus with illumination portion according to claim 1, wherein the electronic apparatus further comprises a diffuser plate located between the transparent illumination portion and the light outputting end for evenly distributing the light emitted by the light outputting end.

8. The electronic apparatus with illumination portion according to claim 7, wherein the light outputting end is located underneath the diffuser plate.

9. The electronic apparatus with illumination portion according to claim 7, wherein the electronic apparatus further comprises a reflecting plate disposed on the diffuser plate for reflecting at least part of the light evenly distributed by the diffuser plate to the transparent illumination portion.

10. The electronic apparatus with illumination portion according to claim 9, wherein the light outputting end is positioned at a lateral side of the diffuser plate.

11. The electronic apparatus with illumination portion according to claim 1, wherein the light guide further comprises:
a first light guide wherein one end of the first light guide is the light receiving end and the other end of the first light guide is a first connecting end;
a second light guide wherein one end of the second light guide is the light outputting end and the other end of the second light guide is a second connecting end; and
a connector for connecting the first connecting end and the second connecting end.

12. The electronic apparatus with illumination portion according to claim 1, wherein the transparent illumination portion is a top face of at lease a press key of a keyboard.

13. The electronic apparatus with illumination portion according to claim 1, wherein the transparent illumination portion is a surface of a button.

14. The electronic apparatus with illumination portion according to claim 1, wherein the transparent illumination portion is an identification symbol region.

15. The electronic apparatus with illumination portion according to claim 1, wherein the light guide is an optical fiber.

16. The electronic apparatus with illumination portion according to claim 15, wherein the optical fiber is plastic fiber.

17. The electronic apparatus with illumination portion according to claim 15, wherein the optical fiber is a polymethyl methacrylate (PMMA) fiber.

18. The electronic apparatus with illumination portion according to claim 15, wherein the optical fiber is glass fiber.
